(19) United States
(12) Patent Application Publication
(10) Pub. No.: US 2011/0284886 A1
(43) Pub. Date: Nov. 24, 2011

(54) LIGHT EMITTING MODULE

(76) Inventors: TAI HSIANG HUANG, TAINAN (TW); KUAN-HSIANG HUANG, TAINAN (TW)

(21) Appl. No.: 12/783,845

(22) Filed: May 20, 2010

(51) Int. Cl. H01L 33/48; H01L 33/62

(52) U.S. Cl. 257/91; 257/E33.056; 257/E33.066

(57) ABSTRACT

A light emitting module is revealed. The light emitting module includes a main substrate disposed with LED lights. The main substrate is connected correspondingly to a connector that is electrically connected with a light holder. A plurality light emitting sets is disposed circularly under the main substrate. Thereby the LED lights on the main substrate project light upward while the light emitting sets provide light under the main substrate and therearound. Thus the light emitting module provides shadow-free illumination. While being used together with a light shade, figures on the light shade are projected and enlarged so as to enhance visual aesthetics.

### BACKGROUND OF THE INVENTION

1. Fields of the Invention

The present invention relates to a light emitting module, especially to a light emitting module that produces non-directional light distribution by light emitting sets disposed circularly under a main light source, a broader range of lighting is provided.

2. Descriptions of Related Art

Light emitting diode (LED) is a directional light source with narrow viewing angle. In order to increase viewing angle of LED, a plurality of techniques have been developed and reported. If the improvement of the viewing angle only depends of the modification of LED chip itself, complicated optical processing is required so as to increase the viewing angle to nearly 180°. Moreover, the luminous flux output is affected and the brightness of the LED is dramatically decreased. When LED is applied to general lights, besides the requirement of power saving and higher light emitting efficiency, the LED light produced must have similar appearance of tungsten lamps available now so as to match reflection structure of light fixtures available now.

As shown in FIG. 6, a LED light bulb available on the market now includes a number of LED lamps 60 are mounted together on a top surface of a circuit substrate 61. The lighting patterns of the LED lamp are adjusted according to the arrangement of the LED lamps 60. However, the flat arrangement makes general LED lights provide a limited viewing angle, about 120°. Compared with conventional tungsten lamps, LED lights are unable to produce non-directional light distribution.

Moreover, refer to Taiwanese Pat. Pub. No. 377524, a LED light electrically connected and installed on a lamp holder is revealed. The LED light includes a conductive connector for electrical connection to the lamp holder; a control base electrically connected with the conductive connector, fixed on the bottom of the conductive connector, and having a first mounting surface facing downward; and a pyramidal base tapered from top to bottom disposed on the first mounting surface and having an inclined second mounting surface. A preset angle is located between the first mounting surface and the second mounting surface. A plurality of LEDs electrically connected with the control base is respectively mounted on and exposed on the first mounting surface and the second mounting surface, and is driven by the control base for emitting light. A light cover shielding the LEDs, and the pyramidal base are fixed on the control base. However, such design has following disadvantages:

1. The viewing angle (range) of LED is still restricted, only a bit larger than 120° shown in FIG. 5. The LED light still unable to provide light in all directions.
2. This is a closed design so that high heat generated by the LED is unable to be released effectively. Thus the LED lifetime is reduced.

Thus there is a need to develop a novel light emitting module that overcomes the disadvantages of the modules available now and has higher practical value.

### SUMMARY OF THE INVENTION

Therefore it is a primary object of the present invention to provide a light emitting module that provides shadow-free illumination for overcoming the shortcoming of techniques available now. By light emitting sets set circularly under a main light source, a broader range of lighting is achieved.

In order to achieve above object, a light emitting module of the present invention includes a main substrate arranged with LED lights and the main substrate is correspondingly connected to a connector that is electrically connected with a light holder. A plurality light emitting sets is disposed circularly under the main substrate. Thereby the LED lights on the main substrate project light upward while the light emitting sets provide light thereunder and therearound. Thus the light emitting module emits light in all directions. When the present invention is used in combination with a light shade, figures on the light shade are projected and enlarged so as to improve visual aesthetics of the figures.

The light emitting set of the present invention consists of a sub-substrate arranged with a plurality of LED lights. The LED lights on the main substrate and on the sub-substrate are connected with one another in series-parallel connections.

A transparent cover is mounted on the main substrate and on each light emitting set respectively. Or an insulating layer is coated on the main substrate and on each light emitting set respectively.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein:

FIG. 1 is a perspective view of an embodiment according to the present invention;

FIG. 2 is an explosive view of an embodiment according to the present invention;

FIG. 3 is a schematic drawing showing an assembled embodiment according to the present invention;

FIG. 4 is a schematic drawing showing another embodiment according to the present invention;

FIG. 5 is a schematic drawing showing a cross section of an embodiment in use according to the present invention;

FIG. 6 is a schematic drawing showing an embodiment of a prior art.

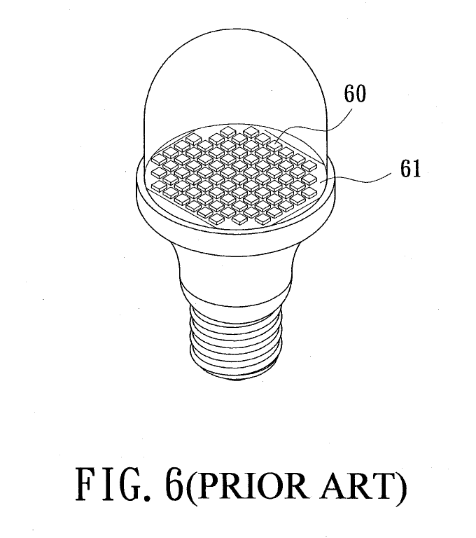

### DETAILED DESCRIPTION OF THE PREFERRED EMBODIMENT

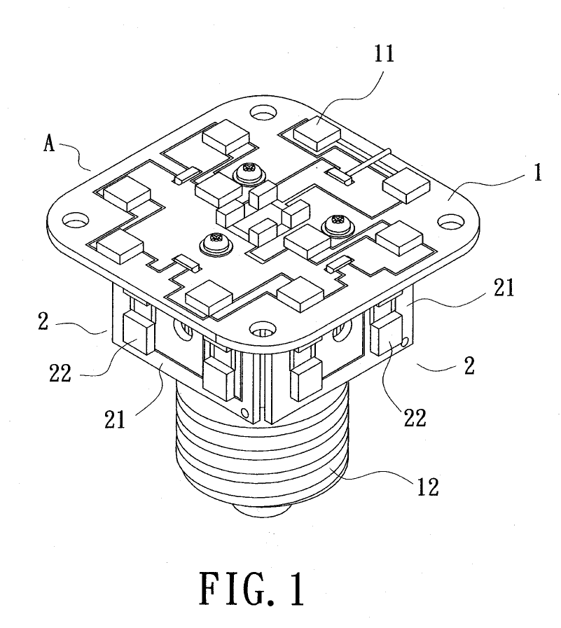

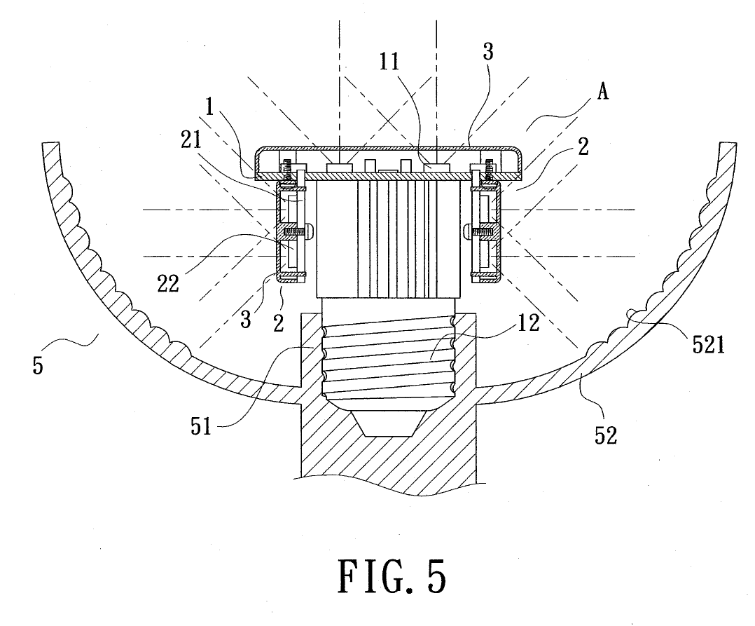

Refer to FIG. 1 and FIG. 5, schematic drawings show a perspective view of an embodiment of a light emitting module A according to the present invention. The light emitting module mainly includes a main substrate 1 disposed with LED lights 11. The main substrate 1 is connected correspondingly to a connector 12 that is electrically connected with a light holder 51.

A plurality light emitting sets 2 is arranged circularly under the main substrate 1. The light emitting set 2 consists of a sub-substrate 21 set with a plurality of LED lights 22 correspondingly.

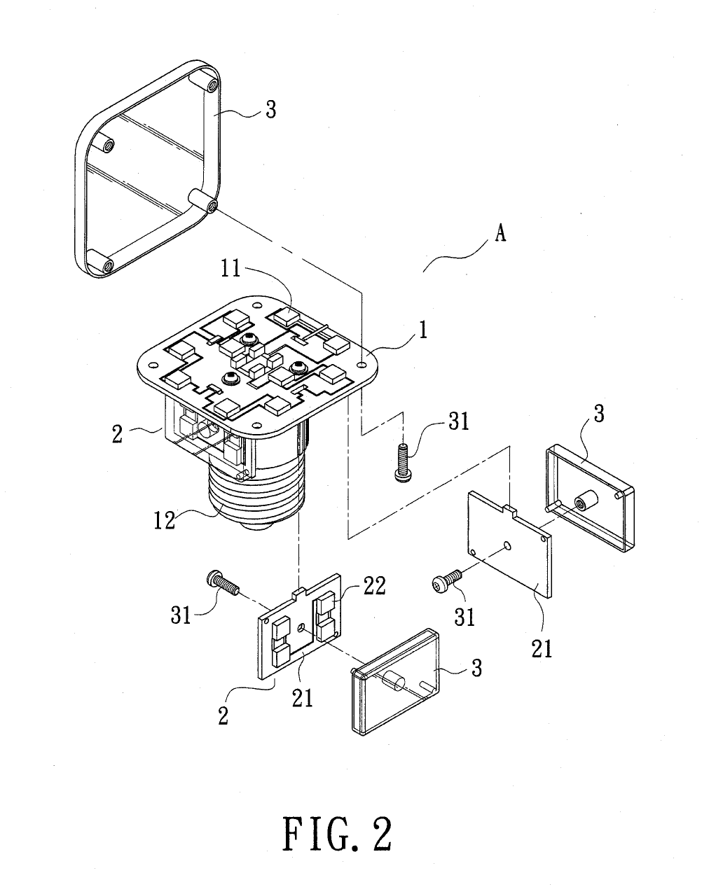

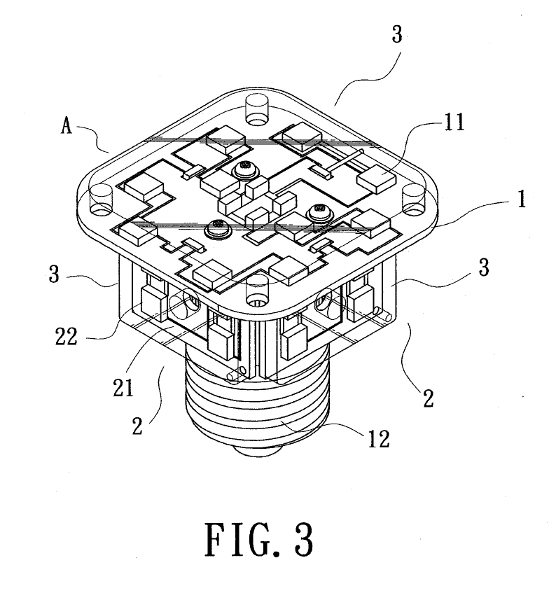

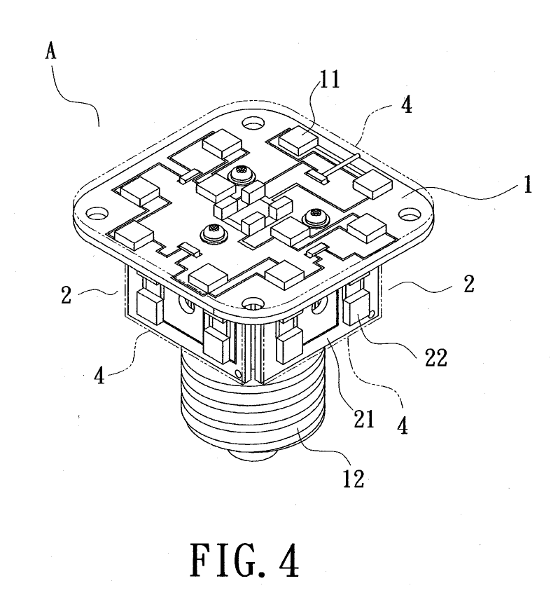

Refer from FIG. 1 to FIG. 5, the light emitting set 2 of the light emitting module A is disposed with a sub-substrate 21 and a plurality of LED lights 22 distributed on the sub-substrate 21. The LED lights 11, 22 on the main substrate 1 and on the sub-substrate 21 are connected with one another in series-parallel connections. When the light emitting module A is in use, the main substrate 1 and each light emitting set 2 are respectively mounted with a transparent cover 3. The transparent cover 3 is fastened on the main substrate 1 and on each light emitting set 2 by threaded parts 31 so that the light emitting module A looks like having light covers, as shown in FIG. 3. Without light covers, the surface of the main substrate 1 and the surface of each light emitting set 2 are coated with an insulating layer 4 directly, as shown in FIG. 4. In use, the light emitting module A is connected with the light holder 51 of a light set 5 by the connector 12. The light set 5 can be a type of light fixtures such as street light, indoor light, reading light, etc. When the light set 5 is designed to use with a light shade 52 with figures 521, as shown in FIG. 5, LED lights 11 on the main substrate 1 of the light emitting module A according to the present invention project light upward while the LED lights 22 of the sub-substrate 21 of the light emitting set 2 emit light thereunder and therearound. Thus the light emitting module A produces 360-degrees shadow-free illumination. Moreover, by displaying the figures 521 on the light shade 52, the figures 521 are projected and enlarged so as to add visual aesthetics of the figures 521.

In summary, compared with the structure and techniques available now, the present invention has following advantages:

1. By arranging light emitting sets circularly under the main light source that projects light upward, the light emitting module emits light in all directions and provides shadow-free illumination.

2. The present invention provides individual heat dissipation space by an open design between the main substrate and tow adjacent light emitting sets. Thus the present invention overcomes the shortcoming of poor heat dissipation. At the same time, the life time of LED is increased.

Additional advantages and modifications will readily occur to those skilled in the art. Therefore, the invention in its broader aspects is not limited to the specific details, and representative devices shown and described herein. Accordingly, various modifications may be made without departing from the spirit or scope of the general inventive concept as defined by the appended claims and their equivalents.

What is claimed is:

1. A light emitting module comprising:
a main substrate disposed with at least one light emitting diode (LED) light, and the main substrate connected to a connector that is electrically connected with a light holder,
wherein a plurality of light emitting sets is disposed circularly under the main substrate and each light emitting set includes a sub-substrate.

2. The device as claimed in claim 1, wherein the light emitting set includes a sub-substrate arranged with at least one LED light.

3. The device as claimed in claim 2, wherein the at least one LED light on the main substrate and the at least one LED light on the sub-substrate are connected in series-parallel connection.

4. The device as claimed in claim 1, wherein a transparent cover is mounted on the main substrate and on each light emitting set respectively.

5. The device as claimed in claim 2, wherein a transparent cover is mounted on the main substrate and on each light emitting set respectively.

6. The device as claimed in claim 4, wherein the transparent cover is fastened by threaded parts.

7. The device as claimed in claim 5, wherein the transparent cover is fastened by threaded parts.

8. The device as claimed in claim 1, wherein an insulating layer is coated on a surface of the main substrate and on a surface of each light emitting set respectively.

9. The device as claimed in claim 2, wherein an insulating layer is coated on a surface of the main substrate and on a surface of each light emitting set respectively.
